(19) United States
(12) Patent Application Publication
(10) Pub. No.: US 2026/0130182 A1
(43) Pub. Date: May 7, 2026

(54) DIELECTRIC ISOLATION STRUCTURES AND METHODS OF MAKING SAME

(71) Applicant: Taiwan Semiconductor Manufacturing Company, LTD., Hsinchu (TW)

(72) Inventors: Chun-Shan Lee, Taipei (TW); Chung-Chuan Tseng, Hsinchu (TW); Meng Chi Hang, Hsinchu (TW); Chien-Lin Tseng, Zhubei (TW)

(21) Appl. No.: 18/934,484

(22) Filed: Nov. 1, 2024

(51) Int. Cl. H01L 21/762; H01L 21/02; H01L 29/06

(52) U.S. Cl. CPC H10P 90/1908; H10D 62/10; H10P 14/6334; H10P 90/1906; H10W 10/014; H10W 10/061; H10W 10/17; H10W 10/181

(57) ABSTRACT

In a method for forming a dielectric isolation structure or container, ion implantation is performed to form a buried implant region in a base semiconductor material. Trenches are formed in the base semiconductor material that access the buried implant region. The buried implant region is removed by etching via the trenches to form a lateral undercut region connected with the trenches. The lateral undercut region and the trenches are filled with dielectric material to form a dielectric bottom region and annular dielectric sidewall of the dielectric isolation structure. By forming of the trenches and the filling of the trenches in two or more iterations, with the removal of the buried implant region being performed after one of these iterations, detachment and self-collapse of the contained portion of base semiconductor material is avoided.

### BACKGROUND

The following relates to integrated circuits (ICs), IC fabrication processes, isolation structures for IC devices and (sub-)circuits, and the like.

For proper IC operation, constituent electronic components (e.g., single electronic devices, or sub-circuits of the IC) may be electrically isolated from one another to avoid deleterious interactions. Providing such isolation can be challenging.

The following discloses dielectric isolation structures with certain advantages as disclosed herein.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates an isolation perspective view of a dielectric isolation structure and an electronic component disposed in the dielectric isolation structure.

FIG. 2 diagrammatically illustrate a cut view of the dielectric isolation structure and electronic component of FIG. 1, further including representative surrounding base semiconductor material.

FIG. 3 diagrammatically illustrates a perspective view of a photolithographically defined buried implant region formed during fabrication of the dielectric isolation structure of FIGS. 1 and 2.

FIG. 4 diagrammatically shows the perspective view of the buried implant region of FIG. 3, with a mapped diagrammatic side sectional view illustrating a typical implanted dopant profile for the buried implant region.

FIGS. 5A and 5B diagrammatically illustrate top and cut views, respectively, of the dielectric isolation structure under fabrication after forming a photolithographically defined buried implant region and a first deep trench etching step.

FIGS. 6A and 6B diagrammatically illustrate top and cut views, respectively, of the dielectric isolation structure under fabrication of FIGS. 5A and 5B after a further lateral etching step that removes the photolithographically defined buried implant region.

FIGS. 7A and 7B diagrammatically illustrate top and cut views, respectively, of the dielectric isolation structure under fabrication of FIGS. 6A and 6B after further steps of first insulator deposition and first chemical mechanical polishing (CMP).

FIGS. 8A and 8B diagrammatically illustrate top and cut views, respectively, of the dielectric isolation structure under fabrication of FIGS. 7A and 7B after a second deep trench etching step.

FIGS. 9A and 9B diagrammatically illustrate top and cut views, respectively, of the dielectric isolation structure of FIGS. 8A and 8B after further steps of second insulator deposition and second CMP.

FIGS. 10A and 10B diagrammatically illustrate top views of variant dielectric isolation structures in which the cross-sections of the deep trenches formed in the first and second deep trench etching steps are of different size and shape.

FIG. 11 diagrammatically illustrates top views of variant dielectric isolation structures in which a photolithographic overlay (OVL) for the second deep trench etching step is shifted relative to the photolithographic overlay for the first deep trench etching step.

FIG. 12 diagrammatically illustrates a top view of a variant dielectric isolation structure fabricated using three deep trench etching steps, with the cross-sections of the deep trenches formed in the first, second, and third deep trench etching steps being of different size and shape.

FIGS. 13A and 13B diagrammatically illustrate top and cut views, respectively, of a dielectric isolation structure grid employing unit cell isolation structures of FIGS. 9A and 9B with a common bottom portion and shared sidewalls.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Vertical isolation for ICs may employ a dielectric layer, for example using a silicon-on-insulator (SOI) wafer where the buried insulator layer provides vertical isolation. However, this does not provide lateral isolation between electronic components of the IC.

For lateral isolation, shallow trench isolation (STI) or deep trench isolation (DTI) can be employed, or a p/n isolation junction can be formed, e.g. by forming an n-type well in a p-type semiconductor substrate. However, p/n isolation junctions have certain disadvantages such as potentially introducing parasitic capacitance, and provide weaker isolation than is provided by a dielectric material.

Dielectric materials provide better isolation than anti-doping-based isolation, with reduced or eliminated parasitic capacitance. Dielectric isolation structures disclosed herein advantageously provide both vertical and lateral isolation employing dielectric material. Isolation methods disclosed herein advantageously enable manufacturing a dielectric isolation structure which includes both a dielectric bottom region and a dielectric sidewall that encircles a portion of the base semiconductor material contained in the dielectric isolation structure. In this way, at least one electronic component disposed in the portion of the base semiconductor material contained in the dielectric isolation structure is isolated from a remainder of the base semiconductor material located outside of the dielectric isolation structure.

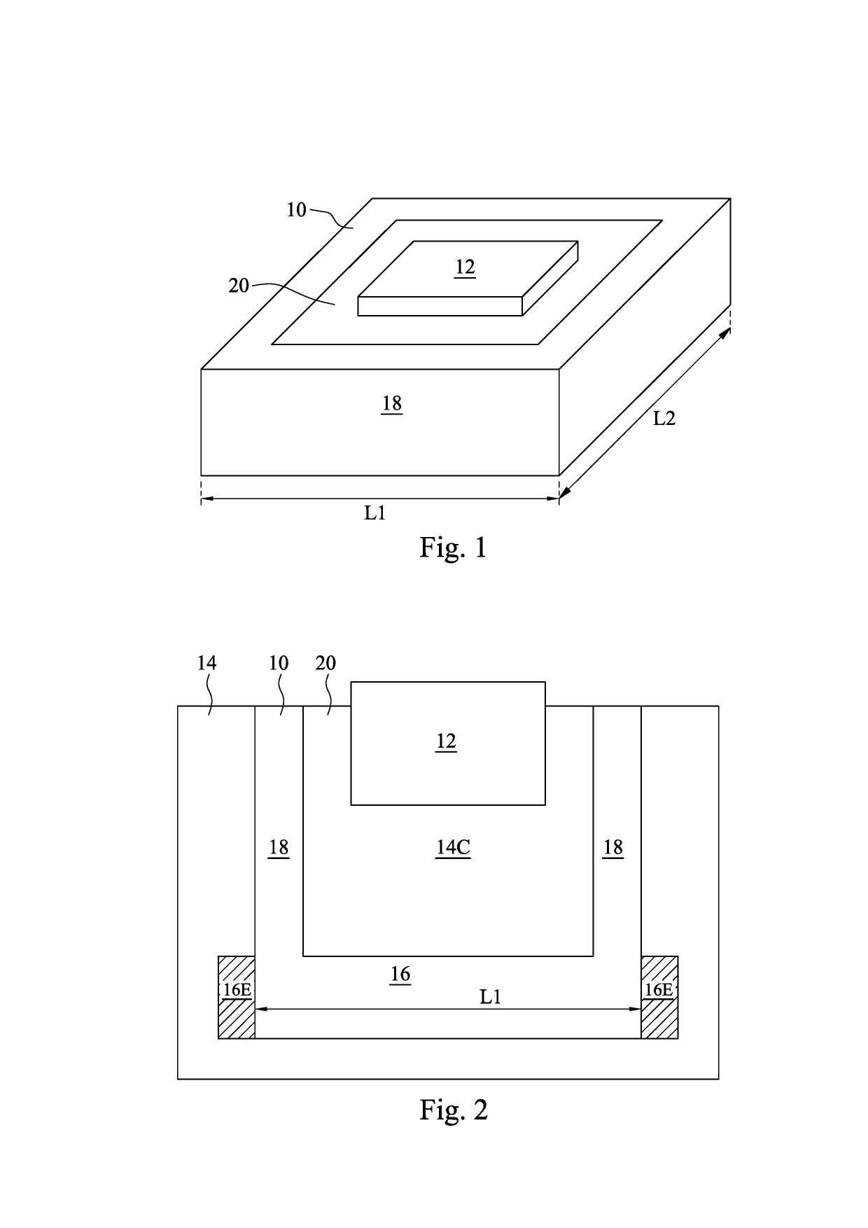

FIGS. 1 and 2 diagrammatically illustrate a dielectric isolation structure 10 for an IC device or circuit 12. FIG. 1 diagrammatically illustrates an isolation perspective view of a dielectric isolation structure 10 and an electronic component 12 disposed in the dielectric isolation structure 10. FIG. 2 diagrammatically illustrate a cut view of the dielectric isolation structure 10 and IC device or circuit 10, further including representative portion of surrounding base semiconductor material 14.

The base semiconductor material 14 may be a semiconductor wafer or substrate such as a silicon wafer, germanium wafer, gallium arsenide (GaAs) wafer, or so forth. In other embodiments, the base semiconductor material 14 may be an epitaxial semiconductor layer or stack of layers deposited on an underlying wafer or substrate, such as an epitaxial silicon, germanium, or silicon-germanium alloy (Si₁₋ₓGeₓ) layer deposited on an underlying silicon wafer via molecular beam epitaxy (MBE), metalorganic chemical vapor deposition (MOCVD), or another epitaxial deposition technique. As some further examples, the base semiconductor material 14 may be a multilayer base semiconductor material such as a silicon/silicon wafer or substrate comprising a silicon layer of a first doping formed on a silicon substrate of a different second doping (e.g., an n-type silicon layer disposed on a p-type silicon substrate, or vice versa) or a germanium/silicon or silicon-germanium (Si₁₋ₓGeₓ) wafer or substrate (e.g., a germanium or Si₁₋ₓGeₓ layer disposed on a silicon substrate); or so forth. These are merely some nonlimiting examples of some embodiments of the base semiconductor material 14.

The electronic component 12 may be a single electronic device, such as a field-effect transistor (FET), bipolar junction transistor (BJT), or other type of transistor, a diode such as a p/n diode, a Schottky diode, or another type of diode, a capacitor, or so forth. In other embodiments, the electronic component 12 may be a (sub-)circuit of an IC comprising two or more electronic devices interconnected to form the (sub-)circuit.

As seen in FIG. 2, the dielectric isolation structure 10 includes a bottom portion 16. As seen in both FIGS. 1 and 2, the dielectric isolation structure 10 further includes a sidewall portion 18 that is connected with a perimeter of the bottom portion 16. As best seen in FIG. 1, the sidewall portion 18 is an encircling sidewall portion 18 that encircles a portion 14C of the base semiconductor material 14 which is contained in the dielectric isolation structure 10. Put another way, the encircling sidewall portion 18 and connected bottom portion 16 form the dielectric isolation structure 10 as a dielectric isolation container 10 which contains the portion 14C of the base semiconductor material 14, so that the at least one electronic component 12 formed in and/or on the portion 14C of the base semiconductor material 14 is isolated from the remainder of the base semiconductor material 14 by the dielectric isolation structure (or container) 10.

In the illustrative example as best seen in FIG. 1, the illustrative dielectric isolation structure 10 has a rectangular lateral perimeter with lateral dimensions L1×L2. However, it is contemplated for the dielectric isolation structure 10 to have a rectangular, hexagonal, octagonal, triangular, or otherwise-shaped lateral perimeter.

In the illustrative examples herein, the encircling sidewall portion 18 of the dielectric isolation structure 10 is connected with the perimeter of the bottom portion 16 of the dielectric isolation structure 10. However, it is alternatively contemplated for the encircling sidewall portion 18 of the dielectric isolation structure 10 to be connected with an interior of the bottom portion 16 – this is diagrammatically shown only in FIG. 2 by diagrammatic depiction of the bottom portion 16 of the dielectric isolation structure 10 being extended by extensions 16E (shown with hatching to indicate this is an optional variant).

The encircling sidewall portion 18 of the dielectric isolation structure 10 and the bottom portion 16 of the dielectric isolation structure 10 is made of one or more dielectric materials, such as silicon oxide, silicon carbide, silicon nitride, a low-k dielectric material (that is, a dielectric material having a dielectric constant lower than the dielectric constant of SiO₂), various combinations thereof, or so forth. As used herein, silicon oxide encompasses SiO₂ or other Si-O stoichiometries, and/or the silicon oxide may optionally be doped silicon oxide.

An upper surface 20 of the contained portion 14C of the base semiconductor material 14 is exposed, and the electronic component 12 (e.g., an IC device or circuit) is fabricated on and/or in the contained portion 14C of the base semiconductor material 14. For example, if the electronic component 12 is a planar FET or planar BJT (or a circuit comprising multiple planar FETs or planar BJTs) then it may be fabricated within the contained portion 14C of the base semiconductor material 14. Alternatively, if the electronic component 12 is a three-dimensional (3D) device such as a finFET, gate-all-around (GAA) FET, or a circuit comprising multiple 3D devices, then a portion of the electronic component 12 may extend above the upper surface 20 of the contained portion 14C of the base semiconductor material 14, as in the diagrammatically illustrated example of FIGS. 1 and 2.

As previously noted, the dielectric isolation structure 10 is a dielectric isolation container 10 which contains the portion 14C of the base semiconductor material 14, so that the at least one electronic component 12 formed in and/or on the portion 14C of the base semiconductor material 14 is isolated from the remainder of the base semiconductor material 14 by the dielectric isolation structure (or container) 10. To maximize this isolation, the dielectric isolation container 10 may advantageously have no openings, gaps, or the like (other than the exposed upper surface 20), so that the isolation of the portion 14C of the base semiconductor material 14 from the remainder of the base semiconductor material 14 is complete. Put another way, the dielectric isolation container 10 may advantageously completely surround the portion 14C of the base semiconductor material 14 (again, except for its exposed upper surface 20), so that there is no electrically conductive path between the contained portion 14C of the base semiconductor material 14 and the remainder of the base semiconductor material 14 located outside of the dielectric isolation container 10.

However, fabricating the dielectric isolation container 10 to provide complete isolation is challenging. One approach might seem to be to remove the portion of the base semiconductor material 14 corresponding to the volume of the dielectric isolation container 10 by a suitable etching technique, and then filling the volume with dielectric material. However, removing the portion of the base semiconductor material 14 corresponding to the volume of the dielectric isolation container 10 would physically detach the (destined to be) contained portion 14C of the base semiconductor material 14 from the remainder of the base semiconductor material 14, resulting in a mechanical failure of the structure (e.g., self-collapse of the contained portion 14C). Moreover, etching the space corresponding to the bottom portion 16 of the dielectric isolation container 10 is challenging, since this is a buried region disposed entirely within the base semiconductor material 14.

Fabrication method embodiments disclosed herein overcome these difficulties. In one fabrication method aspect, the bottom portion 16 of the dielectric isolation container 10 is formed by performing ion implantation to form a buried implant region in the base semiconductor material 14. Trenches are formed in the base semiconductor material accessing the buried implant region, and the buried implant region is removed by performing etching through the trenches to form a lateral undercut region connected with the trenches. A selective etch is employed to etch the doped material of the buried implant region without etching the surrounding base semiconductor material 14, thus forming the lateral undercut region corresponding to the bottom portion 16 of the dielectric isolation container 10. Thereafter, the lateral undercut region and the trenches are filled with dielectric material to form the dielectric bottom region 16 and annular dielectric sidewall 18 of a dielectric isolation structure 10.

Furthermore, to avoid detachment and self-collapse of the (destined to be) contained portion 14C of the base semiconductor material 14 from the remainder of the base semiconductor material 14, the formation of the sidewall 18 may be performed in two or more steps. The forming of the trenches for the sidewall and the filling of the trenches is performed in two or more iterations, and the removing of the buried implant region is performed after one of the iterations of the forming of the trenches. In this iterative sidewall formation approach, the (destined to be) contained portion 14C of the base semiconductor material 14 is never fully detached from the remainder of the base semiconductor material 14. The amount of fractional detachment of the (destined to be) contained portion 14C of the base semiconductor material 14 from the remainder of the base semiconductor material 14 during each iteration can be controlled by the number of iterations. For example, with two iterations, the maximum fractional detachment can be as low as 50% of the circumference of the annular sidewall. By increasing to three iterations the maximum fractional detachment can be decreased to as low as 33% of the circumference of the annular sidewall for each iteration.

In the following, a nonlimiting illustrative example of a fabrication method for fabricating the dielectric isolation structure 10 of FIGS. 1 and 2 is described.

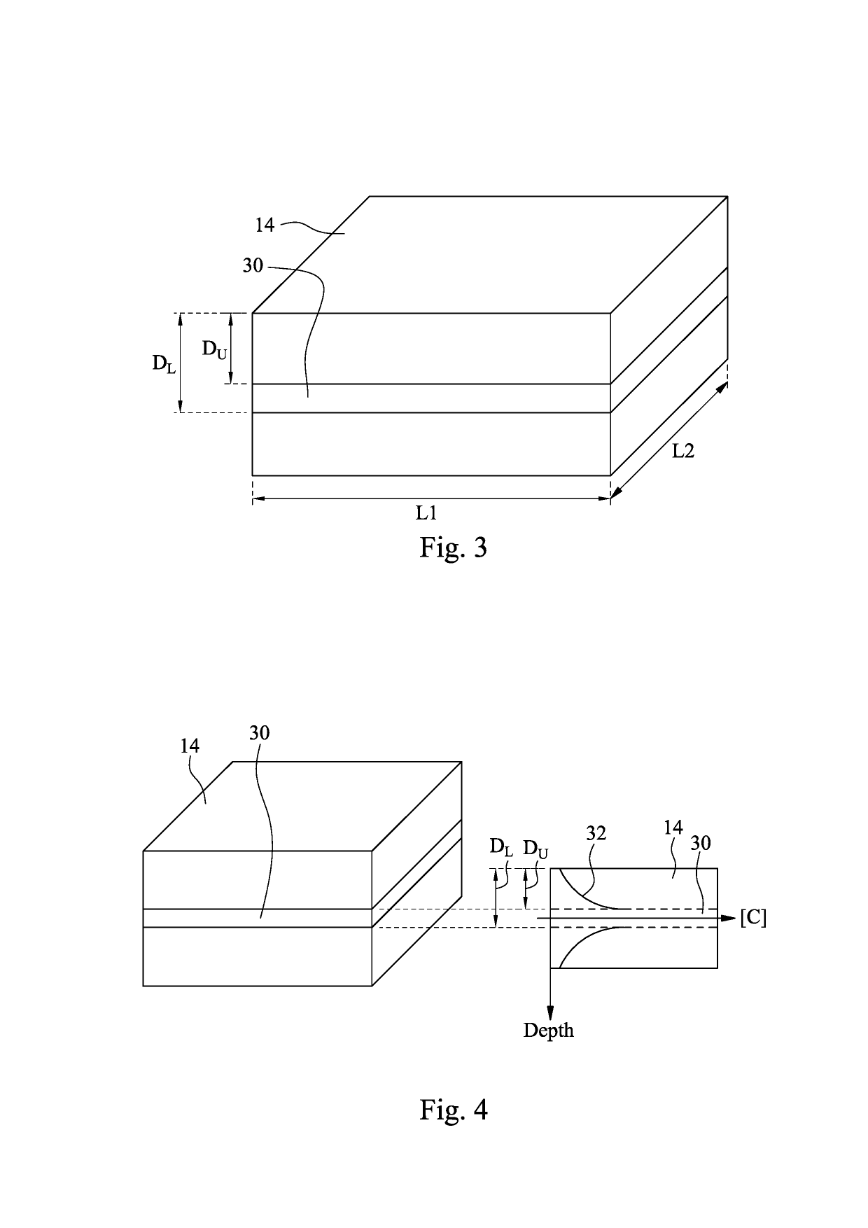

FIG. 3 diagrammatically illustrates a perspective view of a photolithographically defined buried implant region 30 formed during fabrication of an embodiment of the dielectric isolation structure 10. The volume of the buried implant region 30 corresponds to the volume of the bottom portion 16 of the dielectric isolation container 10 being fabricated – hence, the buried implant region 30 has the rectangular lateral perimeter with lateral dimensions L1×L2 corresponding to the bottom portion 16. To form the buried implant region 30, an ion implantation-resistant mask (not shown) is disposed on the surface of the base semiconductor material 14 and is photolithographically patterned to have a window with the lateral dimensions L1×L2, and the ion implantation is thus limited to the lateral dimensions L1×L2 corresponding to the bottom portion 16 by the photolithographically patterned mask. Note that FIG. 3 does not depict portions of the base semiconductor material 14 laterally extending beyond of the area of the L1×L2 area of the buried implant region 30.

The purpose of the buried implant region 30 is to provide a material that can be selectively etched over the surrounding base semiconductor material 14 to form a lateral undercut region that is subsequently filled with a dielectric material to form the bottom portion 16 of the dielectric isolation structure 10. To achieve the desired etch selectivity, in some embodiments the ion implantation forms the buried implant region 30 in the base semiconductor material 14 with an ion dose of at least 10¹⁵ cm⁻³. This is expected to provide sufficient etchant selectivity for a subsequent lateral etching step to selectively remove (i.e., etch away) the buried implant region 30 without also removing a significant portion of the surrounding base semiconductor material 14. The etch selectivity is provided in significant part by the modification (e.g., degradation) of crystallinity of the base semiconductor material in the region of the buried implant region 30, in that the ion implantation and delivered ion dose introduces crystalline defects, disorder, and other structural changes that provide the desired etch selectivity. Hence, the dopant which is implanted by the ion implantation can be chosen from a wide range of elements, such as (but not limited to): boron (B), aluminum (Al), gallium (Ga), indium (In), thallium (Tl), nihonium (Nh), nitrogen (N), phosphorous (P), arsenic (As), antimony (Sb), bismuth (Bi), or so forth.

With continuing reference to FIG. 3 and with further reference to FIG. 4, the ion implantation process produces a distribution 32 of ion dose as a function of depth. FIG. 4 diagrammatically shows the perspective view of the buried implant region 30 of FIG. 3, with a mapped diagrammatic side sectional view illustrating a typical implanted dopant profile 32 for the buried implant region. By controlling ion implantation process parameters, the ion dose distribution 32 can be concentrated in a band extending between an upper (i.e., shallower) depth D_{U} and a lower (i.e., deeper) depth D_{L}, as indicated in the right side of FIG. 4 which diagrammatically plots the ion dose [C] versus Depth. The buried implant region 30 is located in the depth range [D_{U}, D_{L}] and has a width (or thickness) D_{L}-D_{U}. For example, the depth range [D_{U}, D_{L}] may be suitably defined as the depth range over with the ion dose concentration [C] exceeds a minimum dose concentration for providing the desired etching selectivity. While the buried implant region 30 is shown in FIG. 3 and in the left side of FIG. 4 as having abrupt upper and lower boundaries D_{U} and D_{L} respectively, it will be appreciated that these boundaries may be more gradual as diagrammatically indicated by the ion dose distribution 32 shown on the right side of FIG. 4. For forming the desired bottom portion 16 of the dielectric isolation container 10 being fabricated, it is sufficient that the effective width (or thickness) D_{L}-D_{U} of the buried implant region 30 provide the desired thickness of the bottom portion 16 of the dielectric isolation container 10 after the subsequent selective etching and filling with dielectric material.

Notably, at the stage of fabrication shown in FIGS. 3 and 4, the buried implant region 30 is entirely surrounded by the base semiconductor material 14, and hence is not readily accessible for etching.

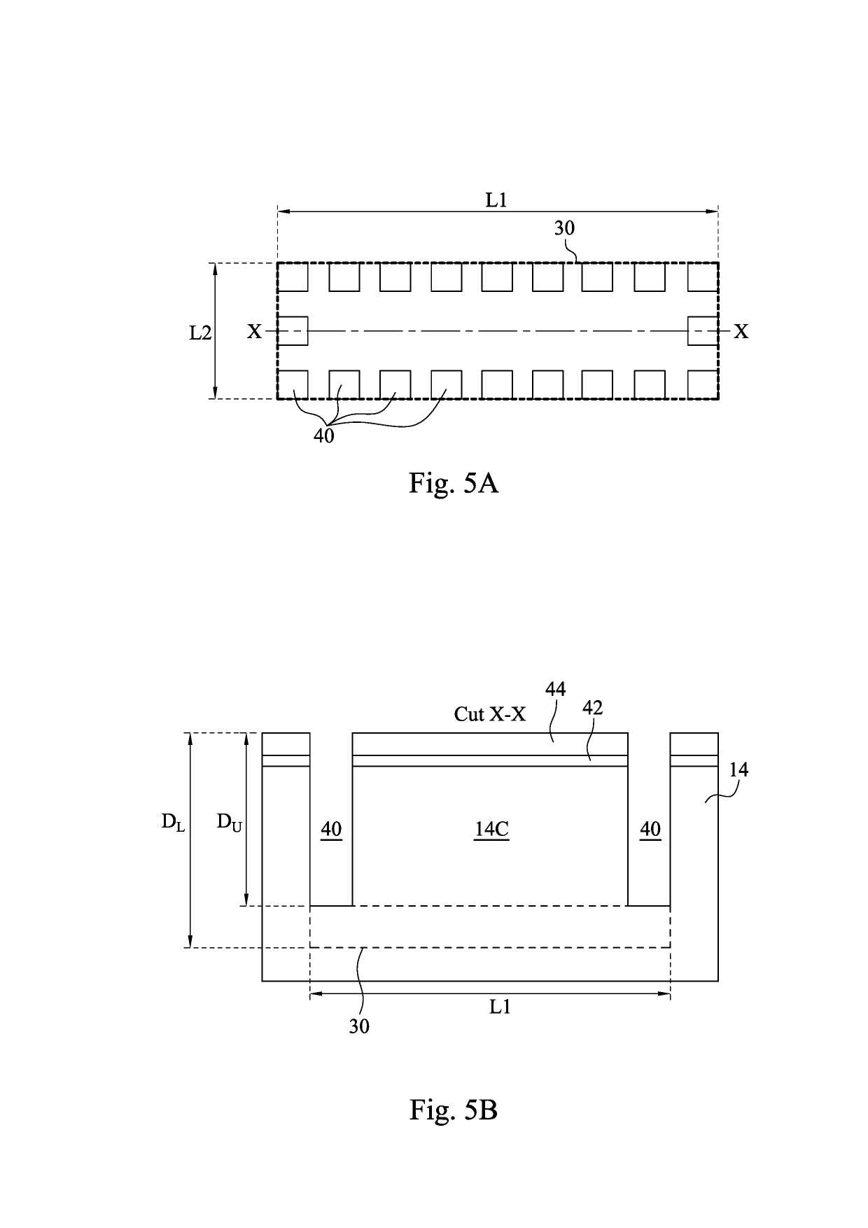

FIGS. 5A and 5B diagrammatically illustrate top and cut views, respectively, of the dielectric isolation structure under fabrication after the formation of the photolithographically defined buried implant region 30 (diagrammatically shown in FIGS. 5A and 5B by dashed lines) and a first deep trench etching step that forms first trenches 40 in the base semiconductor material 14 accessing the buried implant region 30. To provide access to the buried implant region 30, the first trenches 40 have a depth of at least depth D_{U}, corresponding to the upper surface or extend of the buried implant region 30. More generally, the first trenches 40 may have a depth that is equal to or greater than the depth D_{U} corresponding to the upper surface or extend of the buried implant region 30. If the first trenches 40 have depth in the range [D_{U},D_{L}] then the bottoms of the first trenches 40 will lie at or in the buried implant region 30. It is also contemplated for the first trenches 40 to have a depth greater than D_{L}, in which case the first trenches 40 will pass completely through the buried implant region 30.

With particular reference to the top view of FIG. 5A, in the illustrative example the first trenches 40 access (i.e., meet or intersect) the buried implant region 30 at the lateral perimeter of the L1×L2 area of the buried implant region 30. The first trenches 40 are destined to be filled with a dielectric material to form part of the encircling sidewall portion 18 of the dielectric isolation structure 10 (see FIGS. 1 and 2) which encircles the portion 14C of the base semiconductor material 14 which is destined to be contained in the dielectric isolation structure 10.

The first trenches 40 are also sometimes referred to herein as first deep trenches 40, as they go deeply through the base semiconductor material 14 to access the buried implant region 30. In some embodiments, the first trenches 40 are formed by dry etching. In the illustrative example, a hard mask comprising a silicon oxide layer 42 and silicon nitride layer 44 are formed on the surface of the base semiconductor material 14 and photolithographic patterning of the hard mask 42 and 44 is performed to form opening in the hard mask 42 and 44 corresponding to the lateral areas of the first trenches 40, followed by dry etching performed through the mask openings to etch the first trenches 40. In one nonlimiting example for the dry etching in embodiments in which the base semiconductor material 14 is silicon, the dry etchant may comprise CHF₃, but other dry etchants with selectivity for etching the base semiconductor material 14 over the material of the hard mask 42, 44 are contemplated.

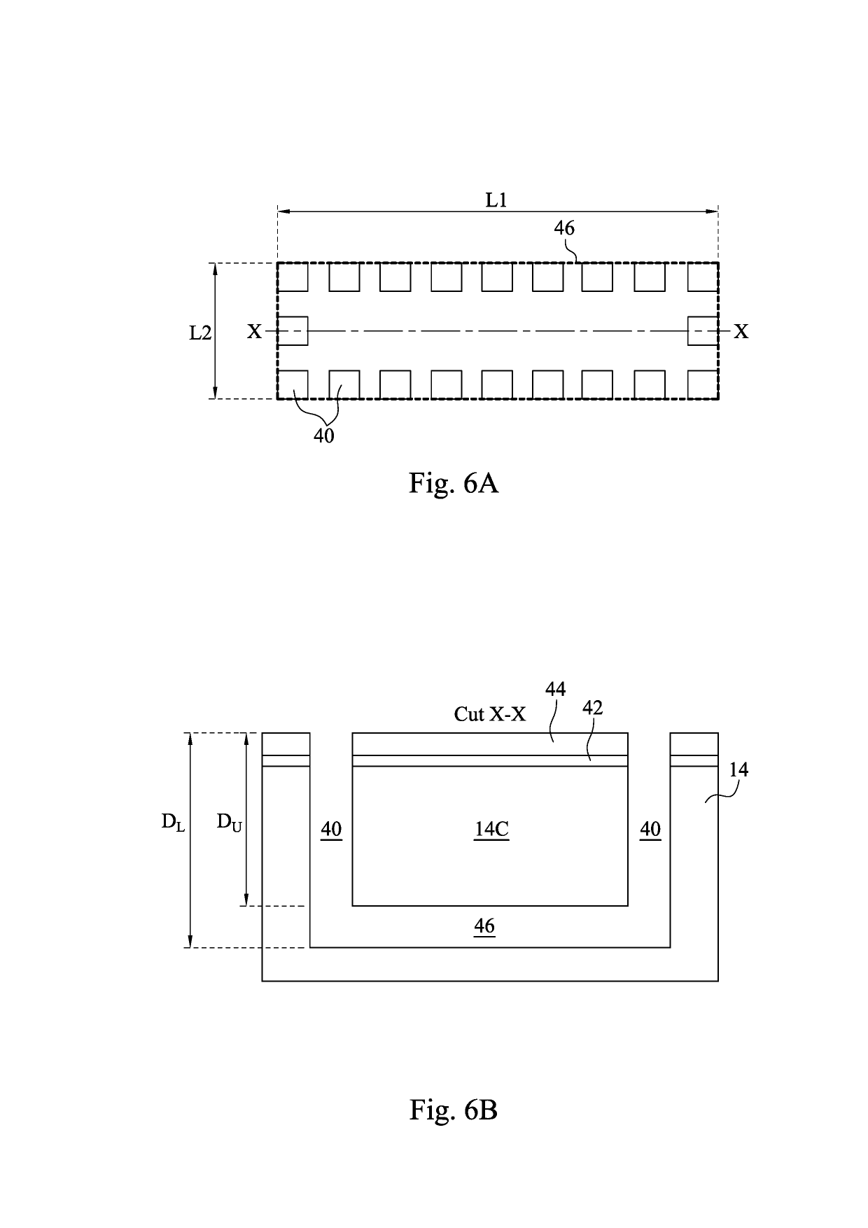

FIGS. 6A and 6B diagrammatically illustrate top and cut views, respectively, of the dielectric isolation structure under fabrication of FIGS. 5A and 5B after a further lateral etching step that removes the photolithographically defined buried implant region 30 to form a lateral undercut region 46. The lateral etching of the buried implant region 30 is performed through the first trenches 40 which provide access of the etchant to the buried implant region 30. The lateral etching of the buried implant region 30 to form the lateral undercut region 46 may, for example, employ wet chemical etching or chemical dry etching (CDE; also known as vapor phase etching or dry chemical etching). CDE employs a reactive gas etchant such as a fluoride- or chlorine-based etchant with high selectivity for etching the buried implant region 30 over the base semiconductor material 14. As previously discussed, the etch selectivity of the lateral etching is provided in significant part by the modification (e.g., degradation) of crystallinity of the base semiconductor material in the region of the buried implant region 30, e.g., crystalline defects, disorder, and other structural changes of the buried implant region 30 that provide the desired etch selectivity. The lateral wet etch or CDE may employ, by way of nonlimiting illustrative example for silicon base semiconductor material, a reactive wet or gas etchant such as a fluoride- or chlorine-based etchant with high selectivity for etching the buried implant region 30 over the base silicon material.

As previously noted with particular reference to FIG. 4, the buried implant region 30 may not have abrupt boundaries at the depths D_{U} and D_{L} due to the non-abrupt boundaries of the concentrated portion of the ion dose distribution 32. Consequently, the lateral undercut region 46 may also have correspondingly non-abrupt edges, for example manifesting as textured interleaved, or other non-abrupt boundaries at the depths D_{U} and D_{L}. This does not impact the vertical isolation of the bottom portion 16 of the dielectric isolation container 10 destined to be formed by filling the lateral undercut region 46 with a dielectric material.

Notably, after the lateral etching step there is a contiguous etched volume within the base semiconductor material 14. The contiguous etched volume includes the first trenches 40 and the lateral undercut region 46. This contiguous etched volume 40, 46 is accessible from outside the base semiconductor material 14 through the upper openings of the first trenches 40, and hence can subsequently be filled with a dielectric material. Of further note, the contiguous etched volume 40, 46 does not fully detach the portion 14C of the base semiconductor material 14 which is destined to be contained in the final dielectric isolation structure 10 from the remainder of the base semiconductor material 14. This is because there remains portions of base semiconductor material 14 located between the first trenches 40 (best seen in FIG. 6A), and these remaining portions located between the first trenches 40 continue to secure the portion 14C of the base semiconductor material 14 with the bulk of the base semiconductor material 14.

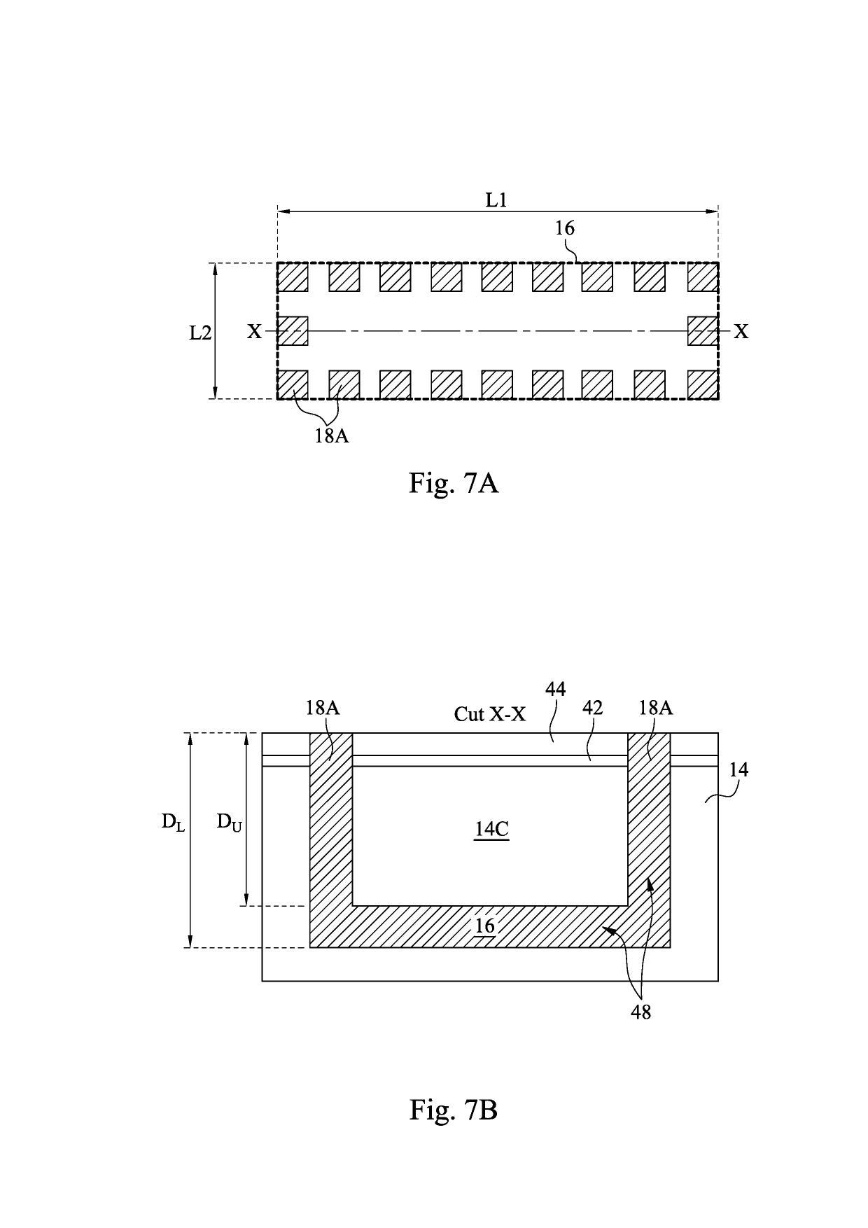

FIGS. 7A and 7B diagrammatically illustrate top and cut views, respectively, of the dielectric isolation structure under fabrication of FIGS. 6A and 6B after further steps of first insulator deposition and first chemical mechanical polishing (CMP). The first insulator deposition fills the lateral undercut region 46 and the first trenches 40 with a first dielectric material 48 to form the bottom 16 of the dielectric isolation structure under fabrication, and to also form first sidewall portions 18A of the dielectric isolation structure under fabrication. More particularly, the first dielectric material 48 filling the first trenches 40 forms the first sidewall portions 18A, and the first dielectric material 48 filling the lateral undercut region 46 forms the bottom portion 16 of the dielectric isolation structure under fabrication. The first sidewall portions 18A constitute portions 18A of what will be the encircling sidewall 18 of the final dielectric isolation structure 10 (see FIGS. 1 and 2). The first insulator deposition may be performed by chemical vapor deposition (CVD) using suitable gas(es) for depositing the first dielectric material 48. By way of some nonlimiting illustrative examples, the first dielectric material 48 may comprise silicon oxide (e.g., SiO₂ or silicon oxide of another stoichiometry), silicon carbide (SiC), silicon nitride (SiN), a low-k dielectric material having a dielectric constant lower than the dielectric constant of SiO₂, or so forth.

The CVD or other deposition of the first dielectric material 48 may overfill the contiguous etched volume 40, 46 with the result that excess first dielectric material may also be deposited on the surface (e.g., on top of the silicon nitride layer 44 in the illustrative example). This excess material is suitably removed by chemical mechanical polishing (CMP) performed after the CVD or other deposition is completed.

Notably, after the processing described with reference to FIG. 7, the portion 14C of the base semiconductor material 14 which is destined to be contained in the final dielectric isolation structure 10 is now secured to the remainder of the base semiconductor material 14 by the dielectric sidewall portions 18A and the dielectric bottom portion 16.

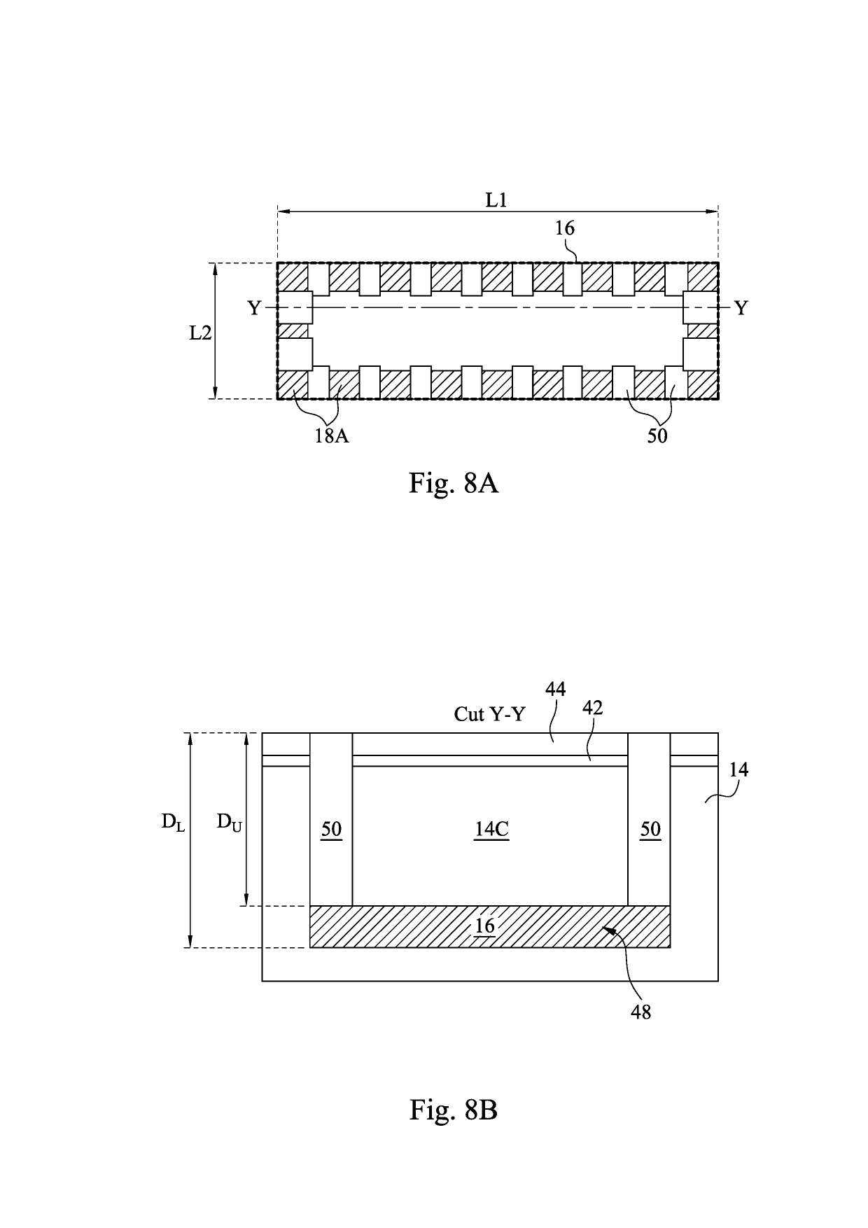

FIGS. 8A and 8B diagrammatically illustrate top and cut views, respectively, of the dielectric isolation structure under fabrication of FIGS. 7A and 7B after a second deep trench etching step. The second deep trench etching step is performed analogously to the first deep trench etching step which formed the first trenches 40 (see FIGS. 5A and 5B and related description). The second deep trench etching step suitably entails photolithographic patterning of the hard mask 42, 44 (or, alternatively, of a second hard mask deposited for the second deep trench etching step, followed by dry etching to from the second trenches 50. The second trenches 50 access the dielectric bottom portion 16. To this end, the bottoms of the second trenches 50 extend downward at least to the depth D_{U}. In some embodiments, the dielectric bottom portion 16 may serve as an etch stop for the second deep trench etching, if the dry etchant is unable to etch the first dielectric material 48, but such etch stop action is not necessary.

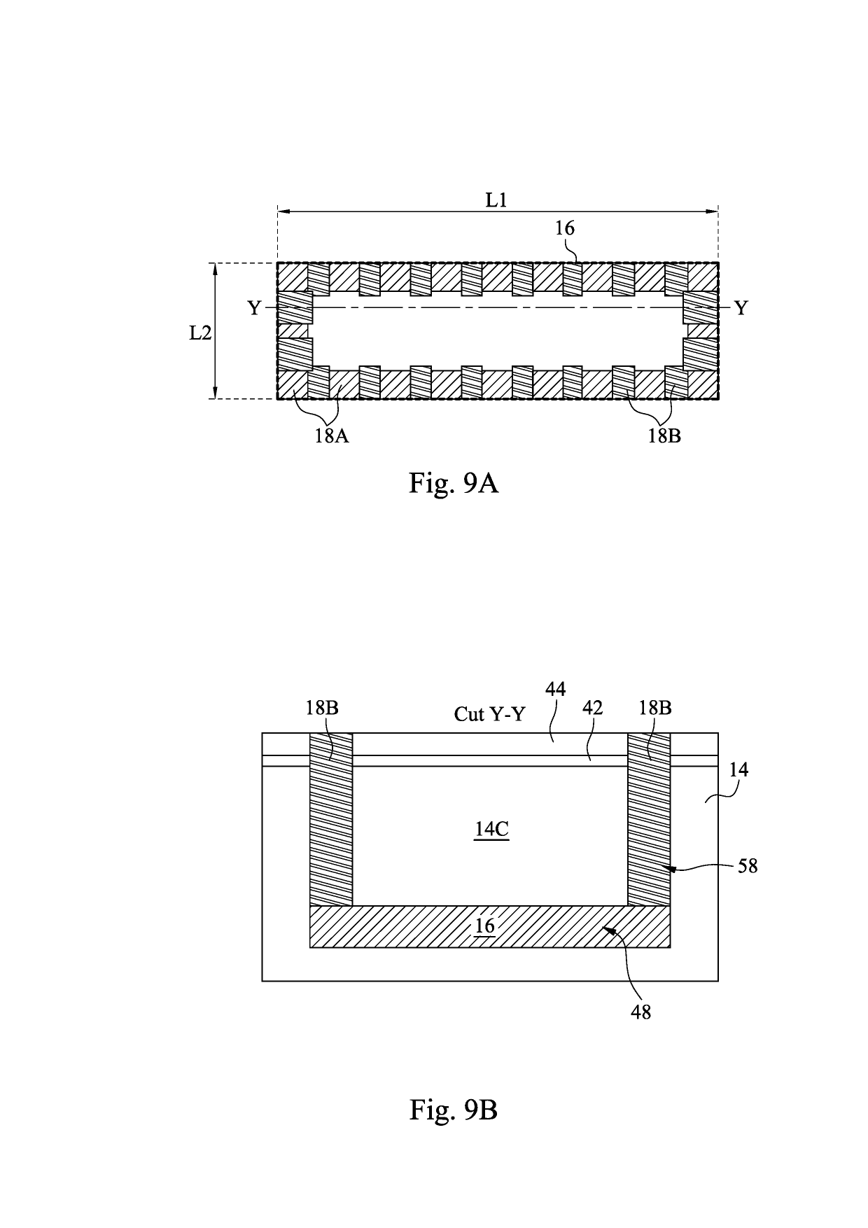

FIGS. 9A and 9B diagrammatically illustrate top and cut views, respectively, of the dielectric isolation structure of FIGS. 8A and 8B after further steps of second insulator deposition and second CMP. The second insulator deposition deposits second dielectric material 58 which fills the second trenches 50 with the second dielectric material 58. The second insulator deposition may suitably employ CVD, and the second dielectric material 58 may comprise silicon oxide (e.g., SiO₂ or silicon oxide of another stoichiometry), silicon carbide (SiC), silicon nitride (SiN), a low-k dielectric material having a dielectric constant lower than the dielectric constant of SiO₂, or so forth. The second dielectric material 58 may be the same as the first dielectric material 48 (e.g., both being silicon oxide, or both being SiC, or both being SiN). Alternatively, the second dielectric material 58 may be different than the first dielectric material 48 (e.g., one being silicon oxide and the other being SiC or SiN).

The CVD or other deposition of the second dielectric material 58 may overfill the second trenches 50 with the result that excess second dielectric material may also be deposited on the surface (e.g., on top of the silicon nitride layer 44 in the illustrative example). This excess material is suitably removed by CMP performed after the CVD or other deposition is completed.

The second etch described with reference to FIGS. 8A and 8B followed by the deposition and CMP described with reference to FIGS. 9A and 9B completes the encircling sidewall 18 of the dielectric isolation structure 10 (see FIGS. 1 and 2) by forming additional (here second) trenches 50 in the base semiconductor material 14 accessing the bottom 16 of the dielectric isolation structure under fabrication and filling the additional trenches 50 with an additional (here second) dielectric material 58 to form additional sidewall portions 18B of the dielectric isolation structure 10. The second sidewall portions 18B are in contact with the first sidewall portions 18A as best seen in FIG. 9A, to form the complete sidewall 18 encircling the portion 14C of the base semiconductor material 14 which is contained in the dielectric isolation structure 10. After the processing described with reference to FIGS. 9A and 9B is complete, the fabrication of the dielectric isolation structure 10 is complete.

As best seen in FIG. 9A, to provide the dielectric isolation structure 10 with no gaps in the isolation, the first sidewall portions 18A and the second (or more generally, additional) sidewall portions 18B of the dielectric isolation structure 10 are in direct contact with one another to form the encircling sidewall 18 of the dielectric isolation structure 10 (see FIGS. 1 and 2). Additionally, as best seen in FIGS. 2, 7B, and 9B the encircling sidewall 18 (made up of portions 18A and 18B in the example of FIGS. 7B and 9B) is in direct contact with the bottom 16 of the dielectric isolation structure 10, again to ensure no gaps in the isolation.

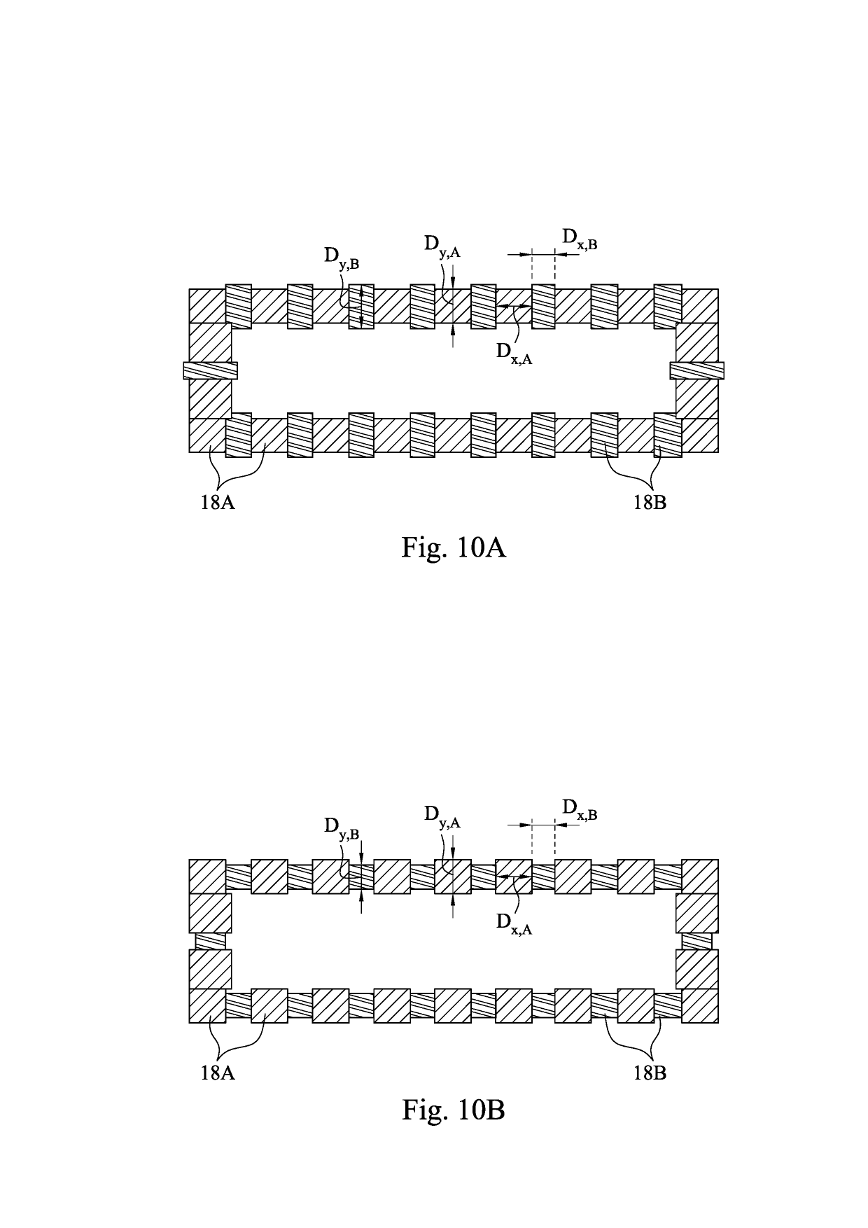

With reference now to FIGS. 10A and 10B, the cross-sectional areas of the first sidewall portions 18A and the second (or more generally, additional) sidewall portions 18B of the dielectric isolation structure 10 can be different. FIGS. 10A and 10B diagrammatically illustrate top views of variant dielectric isolation structures in which the cross-sections of the deep trenches formed in the first and second deep trench etching steps (previously described with reference to FIGS. 5A and 5B, and with reference to FIGS. 8A and 8B, respectively) are of different size and shape.

In the example of FIG. 10A, the first sidewall portions 18A have indicated dimensions (D_{x,A},D_{y,A}) and the second sidewall portions 18B have indicated dimensions (D_{x,B},D_{y,B}), where in FIG. 10A D_{x,A}>D_{x,B} and D_{y,A}<D_{y,B}.

In the example of FIG. 10B, the first sidewall portions 18A have indicated dimensions (D_{x,A},D_{y,A}) and the second sidewall portions 18B have indicated dimensions (D_{x,B},D_{y,B}), where in FIG. 10B D_{x,A}>D_{x,B} and D_{y,A}>D_{y,B}.

More generally: D_{x,A} can be larger than, equal to, or smaller than D_{x,B}; and D_{y,A} can be larger than, equal to, or smaller than D_{y,B}.

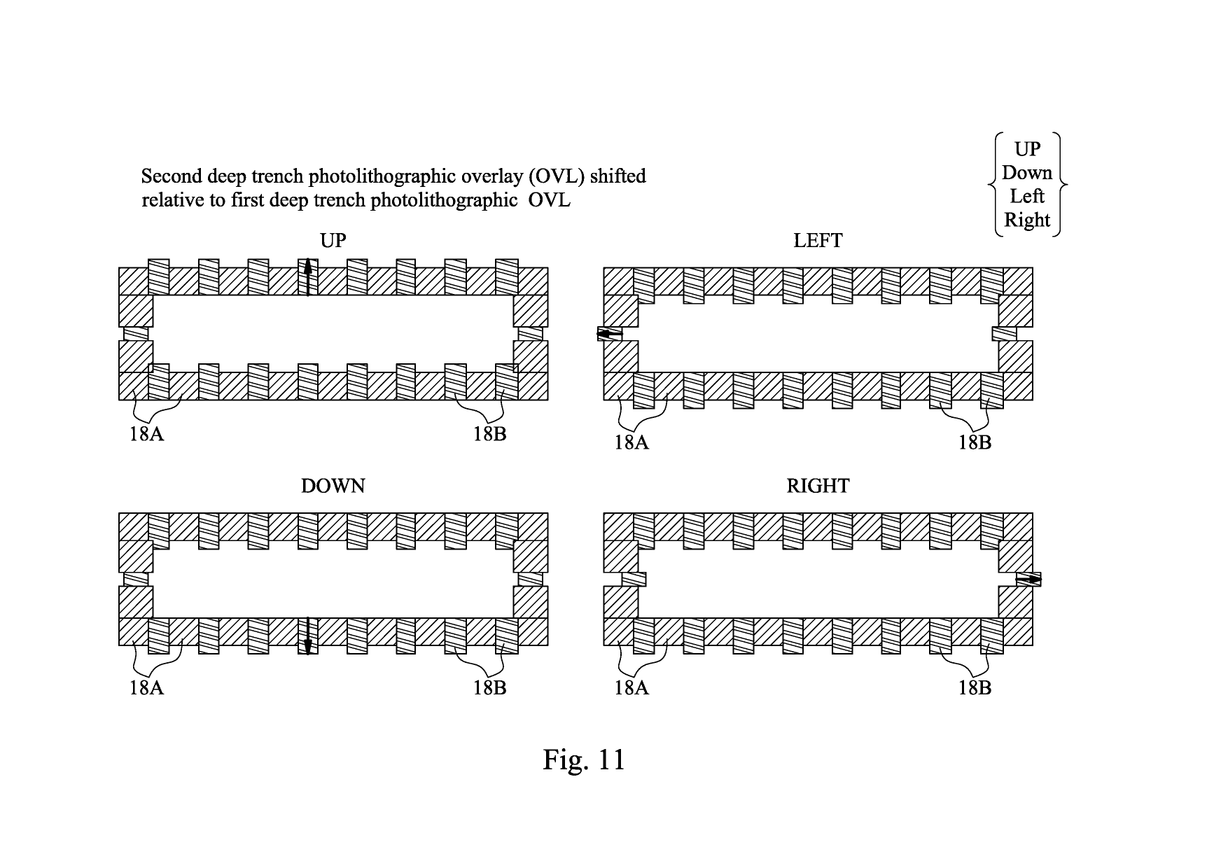

FIG. 11 diagrammatically illustrates top views of variant dielectric isolation structures in which a photolithographic overlay (OVL) for the second deep trench etching step is shifted up, down, left, or right relative to the photolithographic overlay for the first deep trench etching step. Such overlay shift can occur due to manufacturing tolerances and the like, and are not problematic as long as the second sidewall portions 18B are in contact with the first sidewall portions 18A to provide complete isolation.

In the illustrative fabrication process, the encircling sidewall 18 of the dielectric containment structure 10 is formed in two iterations that form the first sidewall portions 18A and the second sidewall portions 18B, respectively. By this approach, the (destined to be) contained portion 14C of the base semiconductor material 14 is never fully detached from the remainder of the base semiconductor material 14 during the fabrication process. This avoids a failure mechanism in which the (destined to be) contained portion 14C of the base semiconductor material moves or is lost entirely during the fabrication process. In the illustrative process the encircling sidewall 18 is formed in two iterations. In this approach, the maximum fractional detachment of the contained portion 14C can be as low as 50% of the circumference of the annular sidewall 18. Put another way, the contained portion 14C remains attached by 50% of its circumference.

If this 50% attachment is insufficient, then the number of iterations can be increased. For example, by increasing to three iterations, the maximum fractional detachment can be decreased to as low as 33% of the circumference of the annular sidewall for each iteration.

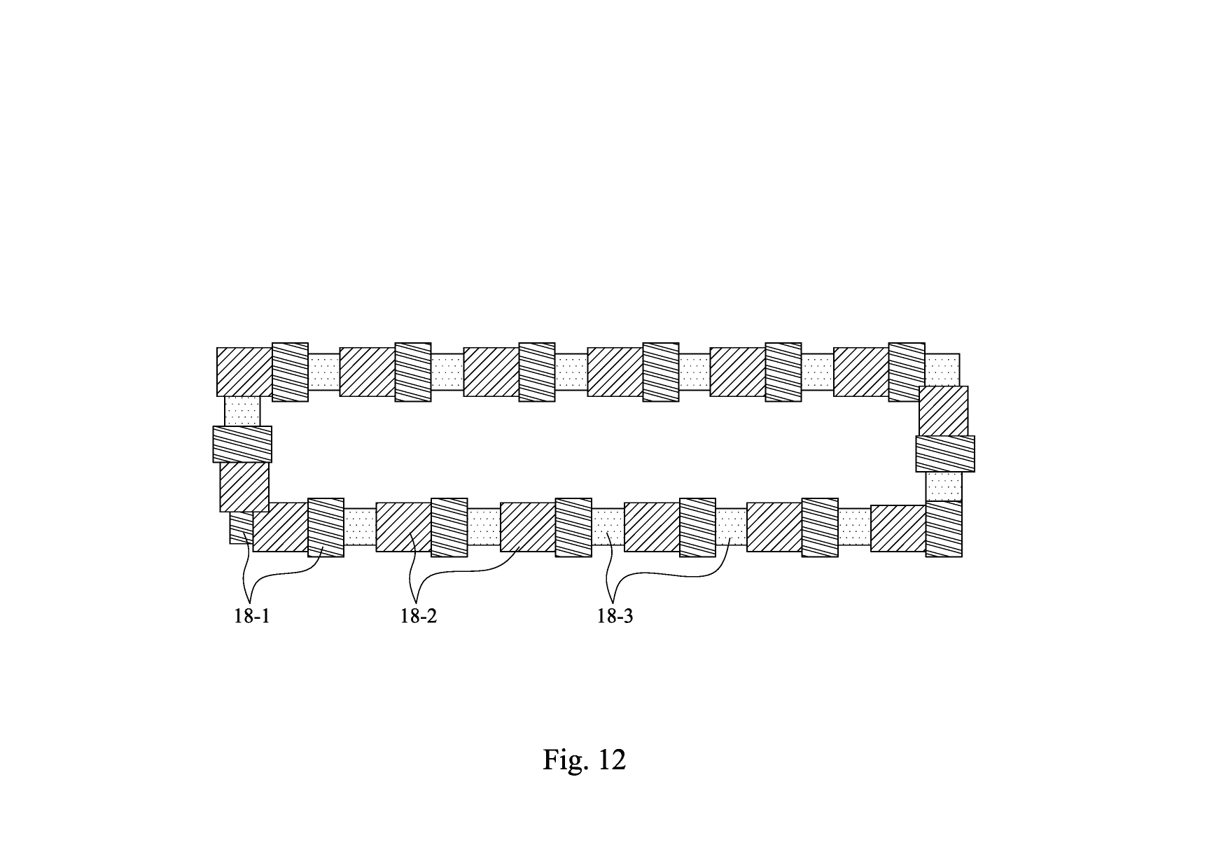

FIG. 12 diagrammatically illustrates a top view of a variant dielectric isolation structure fabricated using three deep trench etching steps, with the cross-sections of the deep trenches formed in the first, second, and third deep trench etching steps being of different size and shape. The three iterations produce first sidewall portions 18 - 1, second sidewall portions 18 - 2, and third sidewall portions 18 - 3, as seen in FIG. 12. Each of the sidewall portions 18 - 1, 18 - 2, and 18 - 3 may be filled with the same dielectric material, or may be filled with different dielectric materials. It will be appreciated that the number of iterations can be further increased above three iterations – for example, four iterations would enable the maximum fractional detachment to be further decreased to as low as 25% of the circumference of the annular sidewall for each iteration.

Referring back to FIGS. 1 and 2, in the foregoing embodiments the dielectric isolation structure 10 provides isolation for a contained portion 14C of the base semiconductor material 14 which is contained in the dielectric isolation structure 10. It will be appreciated that a given IC may include any number of such dielectric isolation structures 10 to provide mutual isolation for contained portions 14C of the base semiconductor material 14 which are contained in the respective dielectric isolation structures 10.

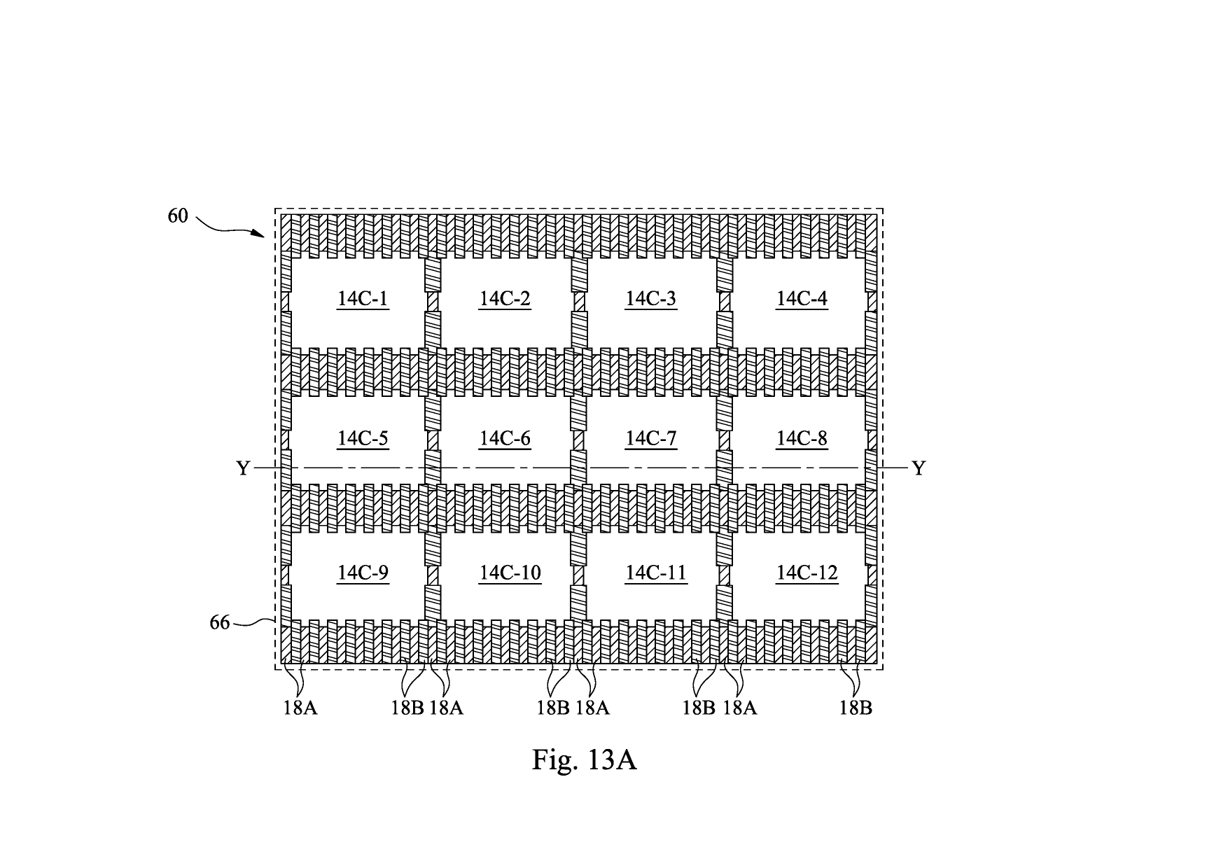

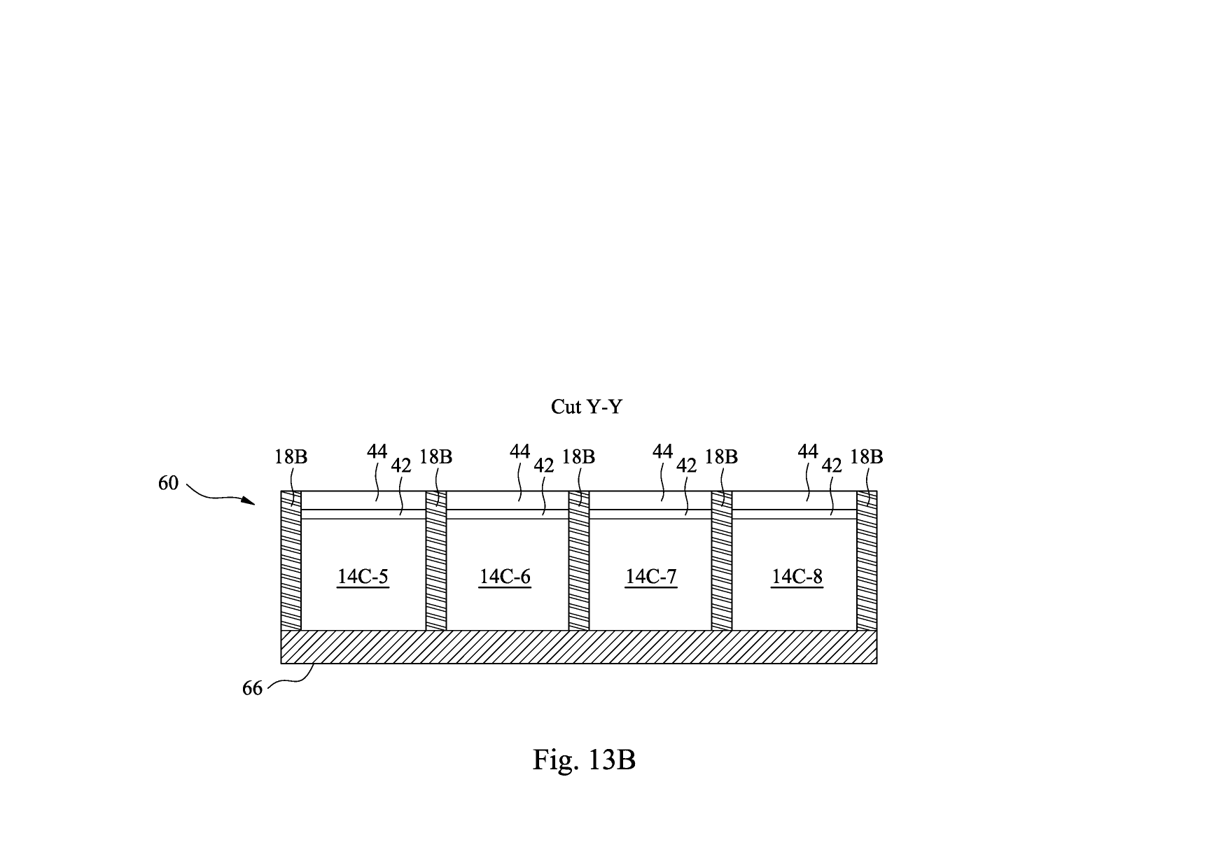

FIGS. 13A and 13B diagrammatically illustrate top and cut views, respectively, of a dielectric isolation structure grid 60 employing unit cell isolation structures of FIGS. 9A and 9B with a common bottom portion 66 and shared sidewalls formed, in the illustrative example, of alternating sidewall portions 18A and 18B. As thus shown, in some embodiments a dielectric isolation structure grid 60 is constructed as a regular grid of instances of the dielectric isolation structure 10 of FIGS. 1 and 2, which in the illustrative example share dielectric sidewalls. In the example of FIGS. 13A and 13B, the repetition employs the “unit cell” dielectric isolation structure of FIGS. 9A and 9B, with the shared sidewalls including alternating first sidewall portions 18A and second sidewall portions 18B. The illustrative example top view of FIG. 13A depicts twelve unit cell dielectric isolation structures arranged in a 4×3 array, providing isolation for twelve contained portions 14C-1, 14C-2, 14C - 3, 14C-4, 14C-5, 14C-6, 14C-7, 14C-8, 14C-9, 14C-10, 14C-11, and 14C-12. Each of these twelve contained portions 14C-1, 14C-2, 14C - 3, 14C-4, 14C-5, 14C-6, 14C-7, 14C-8, 14C-9, 14C-10, 14C-11, and 14C-12 is isolated from all the others, as well as from any other devices on the wafer. FIG. 13B shows Cut Y-Y through the contained portions 14C-5, 14C-6, 14C-7, and 14C-8 (and more particularly through sidewall portions 18B of those cells). More generally the dielectric isolation structure grid 60 may include N times M unit cell dielectric isolation structures arranged in a N×M array and having shared sidewalls providing isolation for N×M contained portions 14C (where N and M are positive integers, and at least one of N and M is two or larger). The dielectric isolation structure grid 60 has a single bottom portion 66 which extends underneath the 4×3 array (or underneath the more general N×M array), and all the sidewalls connect with the bottom portion 66. The bottom portion 66 is also referred to herein as a common bottom portion 66 as it is common to all the unit cell isolation structures making up the dielectric isolation structure grid 60.

The dielectric isolation structure grid 60 is advantageously utilized in ICs and the like which include a one-dimensional (1D) grid of devices or circuits (i.e., a 1D linear array thereof, for which either M=1 or N=1) or a two-dimensional (2D) grid of devices or circuits, in which the devices or circuits are to be mutually isolated from each other (as well as from any other devices or circuits of the IC). For example, the dielectric isolation structure grid 60 could be usefully employed to provide mutual isolation for the pixels of a CMOS image sensor (CIS) having an array of N×M pixels.

The common bottom portion 66 of the dielectric isolation structure grid 60 can be fabricated in the same way as the bottom portion 16 of the previous embodiments, e.g., by forming the photolithographically defined buried implant region 30 (but here with the buried implant region extending laterally over the area destined to be the common bottom portion 66), forming the trenches 40 accessing the buried implant region (cf., FIGS. 5A and 5B), and performing the lateral etching analogous to the previously described step that removes the buried implant region 30 to form a lateral undercut region 46 (cf. FIGS. 6A and 6B). The lateral etching may be performed using wet chemical etching, CDE, or the like.

In the following, some further embodiments are described.

In a nonlimiting illustrative embodiment, an isolation method comprises: performing ion implantation to form a buried implant region in a base semiconductor material; forming first trenches in the base semiconductor material accessing the buried implant region; removing the buried implant region by performing etching through the first trenches to form a lateral undercut region connected with the first trenches; filling the lateral undercut region and the first trenches with a first dielectric material to form a bottom and first sidewall portions of a dielectric isolation structure; completing an encircling sidewall of the dielectric isolation structure by performing at least one instance of forming additional trenches in the base semiconductor material accessing the bottom of the dielectric isolation structure and filling the additional trenches with an additional dielectric material to form additional sidewall portions of the dielectric isolation structure. The first sidewall portions and the additional sidewall portions of the dielectric isolation structure form the encircling sidewall of the dielectric isolation structure which is connected with the bottom of the dielectric isolation structure.

In a nonlimiting illustrative embodiment, an isolation method comprises: performing ion implantation to form a buried implant region in a base semiconductor material; forming trenches in the base semiconductor material accessing the buried implant region; removing the buried implant region by performing etching through the trenches to form a lateral undercut region connected with the trenches; and filling the lateral undercut region and the trenches with dielectric material to form a dielectric bottom region and annular dielectric sidewall of a dielectric isolation structure.

In a nonlimiting illustrative embodiment, an isolation structure includes a dielectric bottom region comprising a dielectric material, and an encircling dielectric sidewall comprising at least one dielectric material. The encircling dielectric sidewall is connected with the dielectric bottom region.

In a nonlimiting illustrative embodiment, an isolation structure includes a dielectric bottom region comprising a dielectric material, and an encircling dielectric sidewall comprising at least one dielectric material. The encircling dielectric sidewall is connected with the dielectric bottom region. The dielectric bottom region and the encircling dielectric sidewall form a dielectric container structure entirely consisting of dielectric material.

In a nonlimiting illustrative embodiment, a structure includes a bottom region comprising a dielectric material, and an encircling dielectric sidewall. The encircling dielectric sidewall is connected with the dielectric bottom region. The encircling dielectric sidewall comprises sidewall portions made of two or more different dielectric materials.

In a nonlimiting illustrative embodiment, an isolation structure includes a dielectric bottom region comprising a dielectric material, and an encircling dielectric sidewall comprising at least one dielectric material. The encircling dielectric sidewall is connected with the dielectric bottom region. The encircling dielectric sidewall comprises sidewall portions made of two or more different dielectric materials, and the dielectric bottom region comprises a single dielectric material which is one of the two or more different dielectric materials of the sidewall portions.

In a nonlimiting illustrative embodiment, in a method for forming a dielectric isolation structure or container, ion implantation is performed to form a buried implant region in a base semiconductor material. Trenches are formed in the base semiconductor material that access the buried implant region. The buried implant region is removed by etching via the trenches to form a lateral undercut region connected with the trenches. The lateral undercut region and the trenches are filled with dielectric material to form a dielectric bottom region and annular dielectric sidewall of the dielectric isolation structure. By forming of the trenches and the filling of the trenches in two or more iterations, with the removal of the buried implant region being performed after one of these iterations, detachment and self-collapse of the contained portion of base semiconductor material is avoided.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An isolation method comprising:
performing ion implantation to form a buried implant region in a base semiconductor material;
forming first trenches in the base semiconductor material accessing the buried implant region;
removing the buried implant region by performing etching through the first trenches to form a lateral undercut region connected with the first trenches;
filling the lateral undercut region and the first trenches with a first dielectric material to form a bottom and first sidewall portions of a dielectric isolation structure;
completing an encircling sidewall of the dielectric isolation structure by performing at least one instance of forming additional trenches in the base semiconductor material accessing the bottom of the dielectric isolation structure and filling the additional trenches with an additional dielectric material to form additional sidewall portions of the dielectric isolation structure;
wherein the first sidewall portions and the additional sidewall portions of the dielectric isolation structure form the encircling sidewall of the dielectric isolation structure which is connected with the bottom of the dielectric isolation structure.

2. The isolation method of claim 1, wherein:
the forming of the first trenches and the forming of the additional trenches comprises forming the first trenches and the additional trenches by photolithographically defined dry etching; and
the removing of the buried implant region by performing etching through the first trenches comprises removing the buried implant region by performing wet chemical etching or chemical dry etching through the first trenches.

3. The isolation method of claim 2, wherein:
the filling of the lateral undercut region and the first trenches with the first dielectric material comprises chemical vapor deposition of the first dielectric material followed by chemical mechanical polishing; and
the filling of the additional trenches with the additional dielectric material comprises chemical vapor deposition of the additional dielectric material followed by chemical mechanical polishing.

4. The isolation method of claim 1, wherein the completing of the encircling sidewall of the dielectric isolation structure includes:
forming first additional trenches accessing the bottom of the dielectric isolation structure and filling the first additional trenches with first additional dielectric material to form first additional sidewall portions of the dielectric isolation structure; and
forming second additional trenches accessing the bottom of the dielectric isolation structure and filling the second additional trenches with second additional dielectric material to form second additional sidewall portions of the dielectric isolation structure;
wherein the first sidewall portions, the first additional sidewall portions, and the second additional sidewall portions of the dielectric isolation structure form the encircling sidewall of the dielectric isolation structure which is connected with the bottom of the dielectric isolation structure.

5. The isolation method of claim 1, wherein one of:
the additional dielectric material is the same as the first dielectric material; or
the additional dielectric material is different from the first dielectric material.

6. The isolation method of claim 1, wherein:
the first dielectric material comprises silicon oxide, silicon carbide, silicon nitride, or a low-k dielectric material having a dielectric constant lower than the dielectric constant of SiO₂; and
the additional dielectric material comprises silicon oxide, silicon carbide, silicon nitride, or a low-k dielectric material having a dielectric constant lower than the dielectric constant of SiO₂.

7. The isolation method of claim 1, further comprising:
forming at least one electronic component in a portion of the base semiconductor material contained in the dielectric isolation structure, wherein the at least one electronic component is isolated from a remainder of the base semiconductor material by the dielectric isolation structure.

8. The isolation method of claim 1, wherein the ion implantation forms the buried implant region in the base semiconductor material with an ion dose of at least 10¹⁵ cm⁻³.

9. The isolation method of claim 1, wherein the first sidewall portions and the additional sidewall portions of the dielectric isolation structure are in contact with one another to form the encircling sidewall of the dielectric isolation structure, and the encircling sidewall is in contact with the bottom of the dielectric isolation structure.

10. An isolation method comprising:
performing ion implantation to form a buried implant region in a base semiconductor material;
forming trenches in the base semiconductor material accessing the buried implant region;
removing the buried implant region by performing etching through the trenches to form a lateral undercut region connected with the trenches; and
filling the lateral undercut region and the trenches with dielectric material to form a dielectric bottom region and annular dielectric sidewall of a dielectric isolation structure.

11. The isolation method of claim 10, wherein:
the forming of the trenches and the filling of the trenches is performed in two or more iterations; and
the removing of the buried implant region is performed after one of the iterations of the forming of the trenches.

12. The isolation method of claim 11, wherein the two or more iterations of the filling of the trenches includes filling the different trenches with at least two different dielectric materials.

13. The isolation method of claim 10, wherein the filling the lateral undercut region and the trenches with dielectric material includes filling the lateral undercut region and the trenches with one or more dielectric materials selected from a group consisting of: silicon oxide, silicon carbide, silicon nitride, or a low-k dielectric material having a dielectric constant lower than the dielectric constant of SiO₂.

14. The isolation method of claim 10, wherein the forming:
the trenches are formed by photolithographically defined dry etching;
the etching performed to remove of the buried implant region comprises wet chemical etching or chemical dry etching through the trenches; and
the lateral undercut region and the trenches are filled with dielectric material by chemical vapor deposition.

15. The isolation method of claim 10, further comprising:
forming at least one electronic component in a portion of the base semiconductor material contained in the dielectric isolation structure, wherein the at least one electronic component is isolated from a remainder of the base semiconductor material by the dielectric isolation structure.

16. A structure comprising:
a bottom region comprising a dielectric material; and
an encircling dielectric sidewall made of two or more different dielectric materials;
wherein the encircling dielectric sidewall is connected with the dielectric bottom region.

17. The structure of claim 16, wherein the bottom region and the encircling dielectric sidewall form a dielectric container structure entirely consisting of dielectric material.

18. The structure of claim 16, wherein the encircling dielectric sidewall comprises sidewall portions alternating between the two or more different dielectric materials going around the encircling dielectric sidewall.

19. The structure of claim 16, wherein the dielectric bottom region comprises a single dielectric material which is one of the two or more different dielectric materials of the sidewall portions.

20. A structure comprising:
a grid of unit structures, each unit structure being a structure as set forth in claim 16;
wherein the bottom regions of the unit structures of the grid of unit structures form a common bottom region of the grid of unit structures; and
wherein the encircling dielectric sidewalls of neighboring unit structures of the grid of unit structures are shared.
